(19) United States
(12) Patent Application Publication
(10) Pub. No.: US 2024/0120220 A1
(43) Pub. Date: Apr. 11, 2024

(54) LOAD LOCK CHAMBERS AND RELATED METHODS AND STRUCTURES FOR BATCH COOLING OR HEATING

(71) Applicant: Applied Materials, Inc., Santa Clara, CA (US)

(72) Inventors: Vishwas Kumar PANDEY, Madhya Pradesh (IN); Ala MORADIAN, Sunnyvale, CA (US)

(21) Appl. No.: 17/961,214

(22) Filed: Oct. 6, 2022

(51) Int. Cl. H01L 21/67; C23C 16/455; C23C 16/458; C23C 16/46; C23C 16/52

(52) U.S. Cl. CPC H01L 21/67201; C23C 16/45502; C23C 16/4583; C23C 16/463; C23C 16/52; H01L 21/67167

(57) ABSTRACT

The present disclosure relates to chambers and related methods and structures for batch cooling or heating. In one implementation, a chamber applicable for use in semiconductor manufacturing includes a base, a lid, and one or more sidewalls between the base and the lid. The base, the lid, and the one or more sidewalls at least partially define an internal volume. The chamber includes a cassette disposed in the internal volume. The cassette includes a first outer plate, a second outer plate spaced from the first outer plate, and a plurality of levels between the first outer plate and the second outer plate. The plurality of levels include a plurality of substrate supports spaced from each other between the first outer plate and the second outer plate. The chamber includes one or more baffles disposed outwardly of the cassette.

### BACKGROUND

### Field

The present disclosure relates to chambers and related methods and structures for batch cooling or heating, in relation to semiconductor manufacturing.

In one or more implementations, a chamber is used to batch heat or cool a plurality of substrates before (e.g., pre-processing) or after (e.g., post-processing) a processing operation (such as an epitaxial deposition operation) for semiconductor applications.

### Description of the Related Art

Semiconductor substrates are processed for a wide variety of applications, including the fabrication of integrated devices and microdevices. Before or after processing operations (such as epitaxial deposition operations), substrates can be heated or cooled. Heating and cooling of substrates can be difficult for batch operations. For example, the location of a substrate can affect the rate at which the substrate is heated or cooled. Additionally, bottleneck effects can occur in areas of the chamber that can cause reduced heat transfer rates and/or non-uniform heating or cooling. Moreover, adjustability can be limited. As an example, increasing gas flow rates may not necessarily cause a corresponding change in heat transfer rates.

Such hindrances can cause reductions in throughput, increased cycle times, increased processing times, reduced modularity in application, increased costs, and increased carbon foot print, and/or non-uniform processing (e.g., deposition) of substrates. Such hindrances can also cause non-uniformities and performance reductions in batch processing operations.

Therefore, a need exists for an improved chamber for batch heating and/or cooling in semiconductor processing.

### SUMMARY

The present disclosure relates to chambers and related methods and structures for batch cooling or heating. In one or more implementations, a chamber is used to batch heat or cool a plurality of substrates before (e.g., pre-processing) or after (e.g., post-processing) a processing operation (such as an epitaxial deposition operation) for semiconductor applications.

In one implementation, a chamber applicable for use in semiconductor manufacturing includes a base, a lid, and one or more sidewalls between the base and the lid. The base, the lid, and the one or more sidewalls at least partially define an internal volume. The chamber includes a cassette disposed in the internal volume. The cassette includes a first outer plate, a second outer plate spaced from the first outer plate, and a plurality of levels between the first outer plate and the second outer plate. The plurality of levels include a plurality of substrate supports spaced from each other. The chamber includes one or more baffles disposed outwardly of the cassette.

In one implementation, a chamber applicable for use in semiconductor manufacturing includes a base, a lid, and one or more sidewalls between the base and the lid. The base, the lid, and the one or more sidewalls at least partially define an internal volume. The chamber includes a cassette disposed in the internal volume. The cassette includes a first outer plate, a second outer plate spaced from the first outer plate, and a plurality of levels between the first outer plate and the second outer plate. The plurality of levels include a plurality of substrate supports spaced from each other. The chamber includes a plurality of baffles disposed outwardly of the cassette. The plurality of baffles include a first baffle positioned adjacent the first outer plate, a second baffle spaced from the first baffle and positioned adjacent the second outer plate, and a third baffle between the first baffle and the second baffle. The chamber includes a plurality of gas inlets formed in the one or more sidewalls. The plurality of gas inlets include one or more first gas inlets aligned between the first baffle and the first outer plate, one or more second gas inlets aligned between the second baffle and the second outer plate, one or more third gas inlets aligned between the first baffle and the third baffle, and one or more fourth gas inlets aligned between the second baffle and the third baffle.

In one implementation, a chamber applicable for use in semiconductor manufacturing includes a base, a lid, and one or more sidewalls between the base and the lid. The base, the lid, and the one or more sidewalls at least partially define an internal volume. The chamber includes a shell disposed in the internal volume. The shell includes a shell base, a shell lid, and one or more shell walls between the shell base and the shell lid. The shell base, the shell lid, and the one or more shell walls at least partially define a shell volume. The shell includes a plurality of gas inlets formed in the one or more shell walls and spaced from each other along the one or more shell walls, and a plurality of gas outlets formed in the one or more shell walls and spaced from each other along the one or more shell walls. The chamber includes a cassette disposed in the shell volume. The cassette includes a first outer plate, a second outer plate spaced from the first outer plate, and a plurality of levels between the first outer plate and the second outer plate. The plurality of levels include a plurality of substrate supports spaced from each other.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic top diagram view of a system for processing substrates, according to one implementation.

FIG. 2 is a schematic partial cross-sectional side view of a chamber, according to one implementation.

FIG. 3 is a schematic top cross-sectional view, along Section 3-3, of the chamber shown in FIG. 2.

FIG. 4 is a schematic top cross-sectional view, along Section 4-4, of the chamber shown in FIG. 2.

FIG. 5 is a schematic partial cross-sectional side view of a chamber, according to one implementation.

FIG. 6 is a schematic top cross-sectional view, along Section 6-6, of the chamber shown in FIG. 5.

FIG. 7 is a schematic partial cross-sectional side view of a chamber, according to one implementation.

FIG. 8 is a schematic top cross-sectional view, along Section 8-8, of the chamber shown in FIG. 7.

FIG. 9 is a schematic partial perspective view of the chamber shown in FIGS. 7 and 8, according to one implementation.

FIG. 10 is a schematic partial cross-sectional side view of a chamber, according to one implementation.

FIG. 11 is a schematic top cross-sectional view of the chamber shown in FIG. 10, along Section 11-11 shown in FIG. 10, according to one implementation.

FIG. 12 is a schematic partial perspective view of the shell shown in FIG. 11, according to one implementation.

FIG. 13 is a schematic partial perspective view of the shell shown in FIG. 10, according to one implementation.

FIGS. 14 and 15 are schematic graphical views of graphs showing temperature (in degrees Celsius) versus time (in seconds), according to one or more implementations.

FIG. 16 is a schematic graphical view of a graph showing temperature (in degrees Celsius) versus time (in seconds), according to one implementation.

FIG. 17 is a schematic partial cross-sectional side view of a chamber, according to one implementation.

FIG. 18 is a schematic top cross-sectional view of the chamber shown in FIG. 17, along Section 18-18 shown in FIG. 17, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to chambers and related methods and structures for batch cooling or heating. In one or more implementations, a chamber is used to batch heat or cool a plurality of substrates before (e.g., pre-processing) or after (e.g., post-processing) a processing operation (such as an epitaxial deposition operation) for semiconductor applications.

The present disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links.

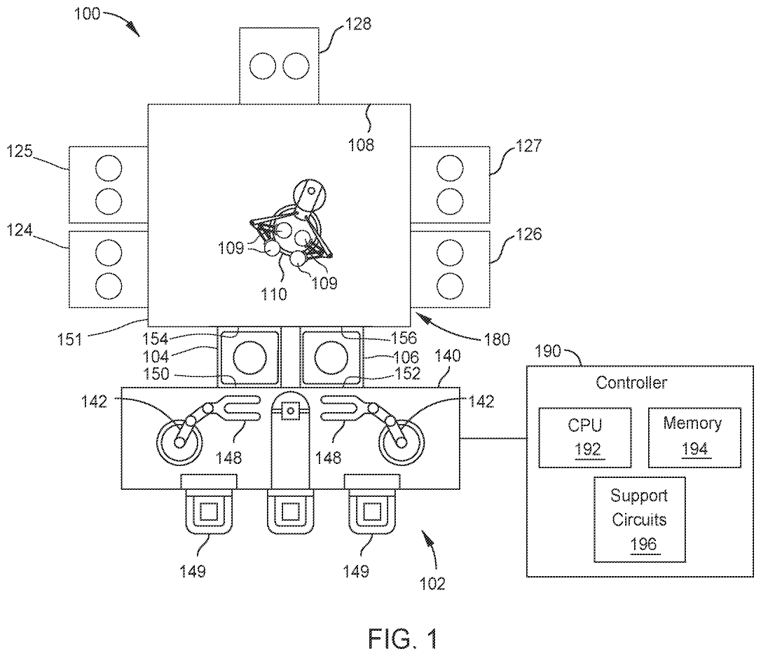

FIG. 1 is a schematic top diagram view of a system 100 for processing substrates, according to one implementation. The system 100 includes a cluster tool 180. The cluster tool 180 includes a factory interface 102, and one or more transfer chambers 108 (one is shown) with a transfer robot 110 disposed therein. The cluster tool 180 includes one or more processing chambers 124, 125, 126, 127 (four are shown) and one or more cleaning chambers 128 (one is shown)—such as a pre-clean chamber—mounted to a mainframe 151 of the single cluster tool 180. Two processing chambers are disposed on opposing sides of the transfer chamber 108, and one cleaning chamber 128 is included, in the implementation shown in FIG. 1. The present disclosure contemplates that a larger or smaller number of processing chambers and/or pre-clean chambers can be used. In one or more embodiments, the transfer robot 110 is configured to simultaneously load and unload a substrate to and from each of two processing volumes of one of the processing chambers 124, 125, 126, 127. In one or more embodiments, the transfer robot 110 is configured to simultaneously load and unload two or more substrates to and from each of two cassettes positioned in the two processing volumes of one of the processing chambers 124, 125, 126, 127. In the implementation shown in FIG. 1, the transfer robot 110 is configured to simultaneously load and unload at least four substrates 109.

In the implementation shown in FIG. 1, the factory interface 102 includes a docking station 140 and factory interface robots 142 to facilitate transfer of cassettes and/or substrates. The docking station 140 is configured to accept one or more front opening unified pods (FOUPs) 149. In one embodiment, which can be combined with other embodiments, each factory interface robot 142 includes a support structure 148 (such as a blade) configured to transfer cassettes and/or substrates from the factory interface 102 to the load lock chambers 104, 106. The load lock chambers 104, 106 have respective doors 150, 152 interfacing with the factory interface 102 and respective doors 154, 156 interfacing with transfer chamber 108. The chambers 124, 125, 126, 127, 128 have respective doors interfacing with the transfer chamber 108. The doors can include, for example, slit openings with slit valves for passing cassettes and/or substrates therethrough by the transfer robot 110 and for providing a seal between respective chambers to prevent a gas from passing between the respective chambers. A door can be open for transferring a cassette and/or substrates therethrough during loading or unloading of chambers. The door can be otherwise closed.

One or more of the load lock chambers 104, 106 can include one or more chamber implementations described herein. As described below for example, each of the load lock chambers 104, 106 can be used to heat or cool a plurality of substrates in a batch manner. The chamber implementations described herein can be used for other chambers of the system 100, such as for one or more temporary storage chambers of the system 100. One or more of the processing chambers 124, 125, 126, 127 can include one or more processing chambers (such as one or more epitaxial deposition chambers) available from Applied Materials, Inc. of Santa Clara, California.

The system 100 includes a controller 190 configured to control the system 100 or components thereof. For example, the controller 190 may control the operation of the system 100 using a direct control of the chambers 124, 125, 126, 127, 128 of the system 100 or by controlling controllers associated with the chambers 124, 125, 126, 127, 128. In operation, the controller 190 enables data collection and feedback from the respective chambers to coordinate and control performance of the system 100.

The controller 190 generally includes a central processing unit (CPU) 192, a memory 194, and support circuits 196. The CPU 192 may be one of any form of a general purpose processor that can be used in an industrial setting. The memory 194, or non-transitory computer readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may include cache, clock circuits, input/output subsystems, power supplies, and the like.

The various methods and operations described herein may generally be implemented under the control of the CPU 192 by the CPU 192 executing computer instruction code stored in the memory 194 (or in memory of a particular processing chamber) as, e.g., a software routine. When the computer instruction code is executed by the CPU 192, the CPU 192 controls the chambers to conduct operations in accordance with the various methods and operations described herein. In one embodiment, which can be combined with other embodiments, the memory 194 (a non-transitory computer readable medium) includes instructions stored therein that, when executed, cause the methods and operations described herein to be conducted. The controller 190 can be in communication with the one or more gas sources 228 and the one or more pumping devices 229, for example, to cause a plurality of operations to be conducted.

Other processing systems in other configurations are contemplated. For example, more or fewer processing chambers may be coupled to a transfer apparatus. In the implementation shown in FIG. 1, the transfer apparatus includes the transfer chamber 108. In other implementations, more or fewer transfer chambers (e.g., one transfer chamber) may be implemented as a transfer apparatus in a system for processing substrates.

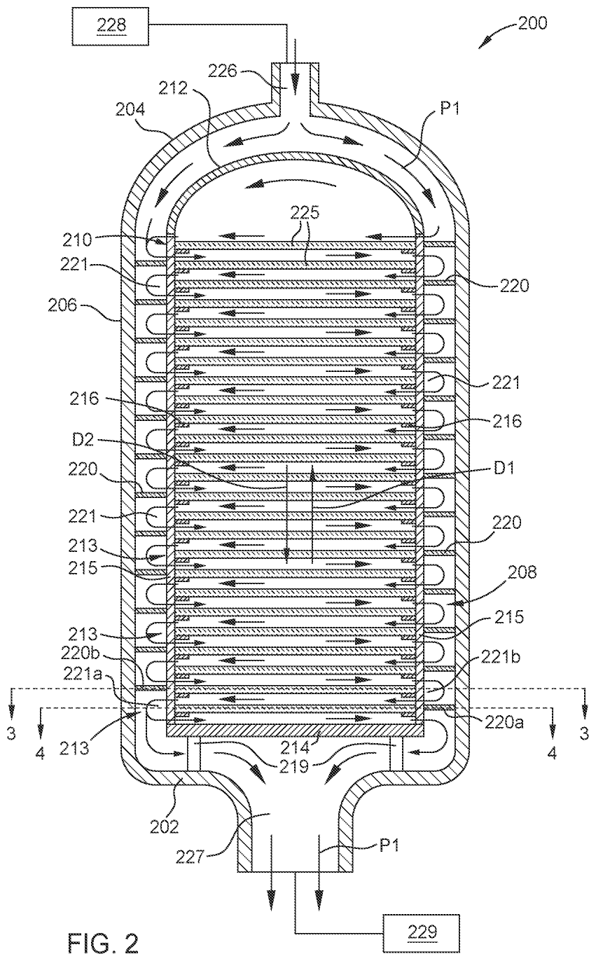

FIG. 2 is a schematic partial cross-sectional side view of a chamber 200, according to one implementation. As discussed above, the subject matter of the chambers (such as the chamber 200) described herein can be used for load lock chambers. The subject matter of the chambers described herein can also be used for other chambers, such as temporary storage chambers. As an example, the temporary storage chambers can be used for the substrates reaching a target temperature, for until a pre-clean chamber or deposition chamber is available, and/or for until a transfer robot is available.

The chamber 200 includes a base 202, a lid 204, and one or more sidewalls 206 between the base 202 and the lid 204. In one or more embodiments, the base 202 and/or the lid 204 is arcuate, such as in the shape of a dome. The base 202, the lid 204, and the one or more sidewalls 206 at least partially define an internal volume 208. In one or more embodiments, the base 202, the lid 204, and/or the one or more sidewalls 206 are coupled together, such as integrally formed with each other.

The chamber 200 includes a cassette 210 disposed in the internal volume 208. The cassette 210 includes a first outer plate 212, a second outer plate 214 spaced from the first outer plate 212, and a plurality of levels 213 between the first outer plate 212 and the second outer plate 214. In one or more embodiments, the first outer plate 212 is arcuate, such as in the shape of a dome.

The plurality of levels 213 include a plurality of substrate supports 216 spaced from each other between the first outer plate 212 and the second outer plate 214. The cassette 210 includes a plurality of support rods 215 extending between the first outer plate 212 and the second outer plate 214. For each level 213 of the plurality of levels 213 a set of substrate supports 216 are coupled to the plurality of support rods 215 and extending inwardly relative to the plurality of support rods 215. In one or more embodiments, the plurality of support rods 215 include three support rods, and each support rod 215 includes one or more substrate supports 216. In one or more embodiments, each substrate support 216 includes a ledge, such as a pin or an arcuate ring segment. The cassette 210 can be supported in the chamber 200, for example, using the second outer plate 214 supported by the base 202 using one or more support structures 219. The one or more support structures 219 can include beams and/or can be circular, cylindrical, and/or rectangular in shape.

The chamber 200 includes one or more baffles 220 disposed outwardly of the cassette 210. The one or more baffles 220 are mounted to the one or more sidewalls 206. The present disclosure contemplates that the one or more baffles 220 can be coupled to the one or more sidewalls 206, such as integrally formed with the one or more sidewalls 206. The plurality of support rods 215 are positioned between the one or more baffles 220 and the plurality of substrate supports 216. The one or more baffles 220 each include an arcuate ring having a flow opening 221 to define an arcuate ring segment for the respective baffle 220. A baffle 220 is included for each level 213 of the cassette 210. In the implementation, shown in FIG. 2, the chamber 200 includes twenty-five levels 213 and twenty five baffles 220. Each level 213 of the cassette 210 supports a substrate 225 of a plurality of substrates 225. Other numbers (such as higher numbers or lower numbers) are contemplated for the levels 213, the substrates 225, and the baffles 220.

In the implementation shown in FIG. 2, the one or more baffles 220 include a first baffle 220a having a first flow opening 221a and a second baffle 220b spaced from the first baffle 220a. The second baffle 220b has a second flow opening 221b. The second flow opening 221b is offset from the first flow opening 221a in a direction D1 from the second outer plate 214 and toward the first outer plate 212.

The chamber 200 includes one or more gas inlets 226 formed in the lid 204 and outwardly of the first outer plate 212, and one or more gas outlets 227 formed in the base 202 and outwardly of the second outer plate 214. The one or more gas inlets 226 are in fluid communication with one or more gas sources 228 that are configured to supply one or more purge gases P1 to the internal volume 208 of the chamber 200. The one or more purge gases P1 include gas(es) that are inert or have a low reactivity. In one or more embodiments, the one or more purge gases P1 include one or more of argon (Ar), helium (He), hydrogen (H₂), nitrogen (N₂), and/or any other purge gas(es). The one or more gas outlets 227 are in fluid communication with one or more pumping devices 229 (such as one or more vacuum pumps) that are configured to exhaust the one or more purge gases P1 from the internal volume 208 of the chamber 200.

During a heat transfer operation that simultaneously heats or cools the substrates 225, the one or purge gases P1 are supplied to the internal volume 208 at a target temperature. The one or more purge gases P1 can be heated or cooled to the target temperature prior to entering the internal volume 208. The target temperature is greater than (for heating, e.g. pre-processing heating of the substrates 225) or lesser than (for cooling, e.g., post-processing cooling of the substrates 225) a reference temperature. The target temperature and/or the reference temperature can depend upon subsequent operations or process temperature parameters (such as process temperature parameters of the subsequent operations). In one or more embodiments, the reference temperature is a processing temperature that will be used—or has been used—for the substrates 225 during a deposition operation that forms one or more layers on the substrates 225. In one or more embodiments, the target temperature is within a range of 100 degrees Celsius to 400 degrees Celsius (such as for pre-clean). In one or more embodiments, the target temperature is within a range of 350 degrees Celsius to 1100 degrees Celsius (such as for post-processing cooling where additional processing is subsequently conducted), such as within a range of 800 degrees Celsius to 1100 degrees Celsius. In one or more embodiments, the target temperature is 30 degrees Celsius or higher (such as after the end of processing where the substrate is then stored). The deposition operation can be for example an epitaxial operation, a chemical vapor deposition (CVD) operation, an atomic layer deposition (ALD) operation, and/or a physical vapor deposition (PVD) operation. Other processing operations are contemplated, before or after which the chamber 200 may be used for heating and/or cooling.

The baffles 220 having the flow openings 221 facilitate guiding the one or more purge gases P1 over front surfaces and backside surfaces of each of the substrates 225 to heat or cool the substrates 225. For example, the baffles 220 having the flow openings 221 facilitate guiding the one or more purge gases P1 between the substrates 225, reducing or eliminating bottleneck effects that would otherwise concentrate flow of the one or more purge gases P1 outwardly of the substrates 225. The chamber 200 facilitates higher purge gas P1 velocities between the substrates 225 and more convection effects between the one or more purge gases P1 and the substrates 225, which facilitates increased heat transfer coefficients, batch heating and/or cooling of substrates, reduced cycle times and processing times, reduced operating cost, reduced carbon foot print that is facilitated by better utilization of purge gas, increased throughout, increased cooling and/or heating rates, adjustability of gas flow rates and heat transfer rates, and modularity in application. As an example, the chamber 200 facilitates a higher increase in heat transfer when a gas flow rate of the one or more purge gases P1 is increased.

In the implementation shown in FIG. 2, the flow openings 221 of the baffles 220 are offset from each other in an alternating arrangement in a flow direction D2 (which is opposite of the direction D1) such that there is no line-of-sight through the flow openings 221 in the flow direction D2. The alternating arrangement defines a serpentine gas flow pattern that includes linear sections (between the substrates 225) and turns (outwardly of the substrates 225).

In one or more embodiments, each of the first outer plate 212, the second outer plate 214, the support rods 215, the one or more baffles 220, the base 202, the lid, 204, and the one or more sidewalls 206 is formed of aluminum. Other materials are contemplated for the chamber 200, such as materials to reduce costs and/or improve heat transfer rate(s).

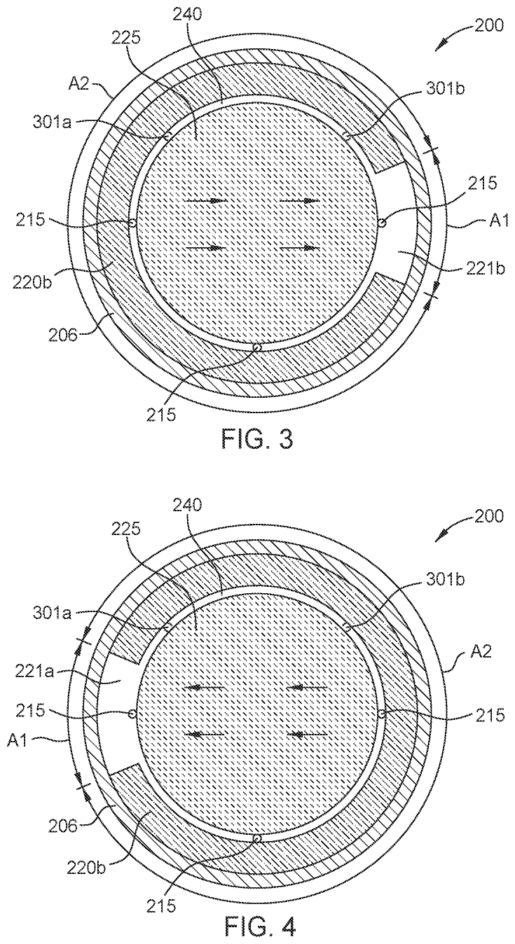

FIG. 3 is a schematic top cross-sectional view, along Section 3-3, of the chamber 200 shown in FIG. 2. The flow opening 221 of each baffle 220 is defined by an angle A1 that is 10 degrees or larger, such as 30 degrees or larger. In one or more embodiments, the angle A1 is within a range of 55 degrees to 65 degrees. In one or more embodiments, the angle A1 is about 60 degrees. Each baffle 220 is an arcuate ring segment that is a C-ring segment. An angle A2 of the arcuate ring segment is equal to 360 degrees minus the angle A1 of the flow opening 221. As an example, the angle A2 of the arcuate ring segment 330 degrees if the angle A1 of the flow opening 221 is 30 degrees.

An annular gap 240 is between the substrates 225 and the one or more baffles 220. In one or more embodiments, the annular gap 240 is about 5.0 mm or lower. In one or more embodiments, the annular gap 240 is about 2.0 mm. The size of the annular gap 240 can depend on process parameters and/or performance parameters.

The locations of the support rods 215 are shown in FIG. 3 for visual clarity purposes in relation to FIG. 2. In one or more embodiments, the two support rods 215 that are aligned horizontally with each other within FIG. 3 can be moved to the two locations 301a, 301b shown in ghost in FIG. 3, such that the three support rods 215 can be disposed in a triangular arrangement.

FIG. 4 is a schematic top cross-sectional view, along Section 4-4, of the chamber 200 shown in FIG. 2. As shown in FIGS. 3 and 4, the flow openings 221 of the baffles 220 are disposed on opposite sides of the internal volume 208 in the alternating arrangement.

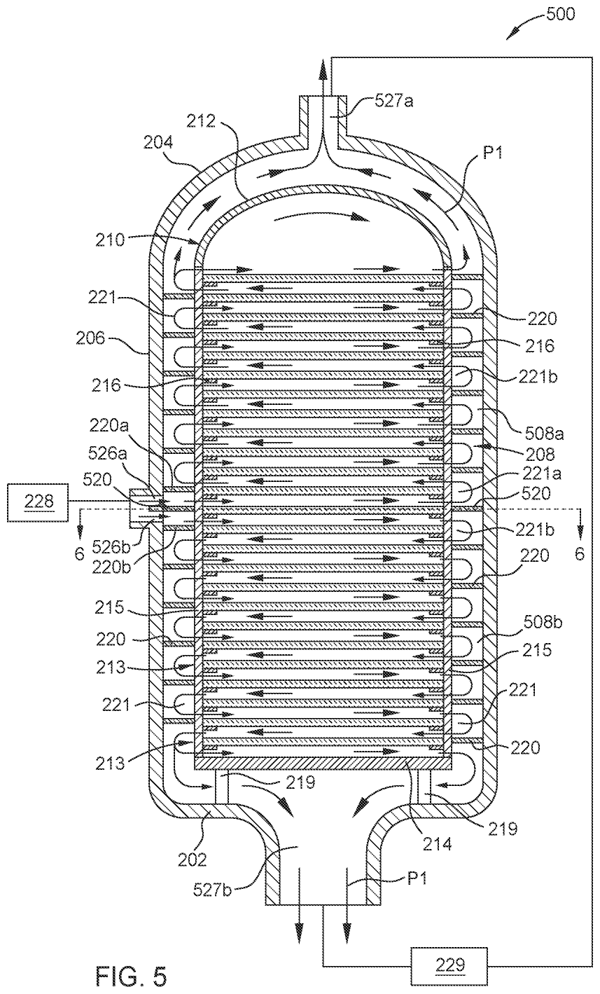

FIG. 5 is a schematic partial cross-sectional side view of a chamber 500, according to one implementation. The chamber 500 is similar to the chamber 200 shown in FIG. 2, and may include one or more features, aspects, components, operations, and/or properties thereof.

In the chamber 500, the one or more baffles include a first baffle 220a having a first flow opening 221a, and a second baffle 220b spaced from the first baffle 220a. The second baffle 220b has a second flow opening 221b. The chamber 500 includes a third baffle 520 between the first baffle 220a and the second baffle 220b. The third baffle 520 has a solid ring. In one or more embodiments, the third baffle 520 is a middle baffle that aligns with a middle level 213 of the plurality of levels 213.

The solid ring of the third baffle 520 divides the internal volume 208 into a first side 508a and a second side 508b such that the one or more purge gases P1 are split to each side 508a, 508b. On each side of the third baffle 520, the flow openings 221 of the baffles 220 are offset from each other in the alternating arrangement such that the serpentine gas flow pattern is defined on each side of the third baffle 520.

The chamber 500 includes a first gas inlet 526a formed in the one or more sidewalls 206 on the first side of the third baffle 520, and a second gas inlet 526b formed in the one or more sidewalls 206 on the second side of the third baffle 520. The chamber 500 includes a first gas outlet 527a formed in the lid 204 and outwardly of the first outer plate 212, and a second gas outlet 527b formed in the base 202 and outwardly of the second outer plate 214.

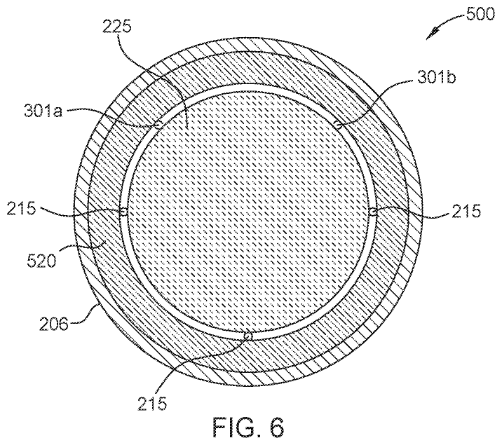

FIG. 6 is a schematic top cross-sectional view, along Section 6-6, of the chamber 500 shown in FIG. 5.

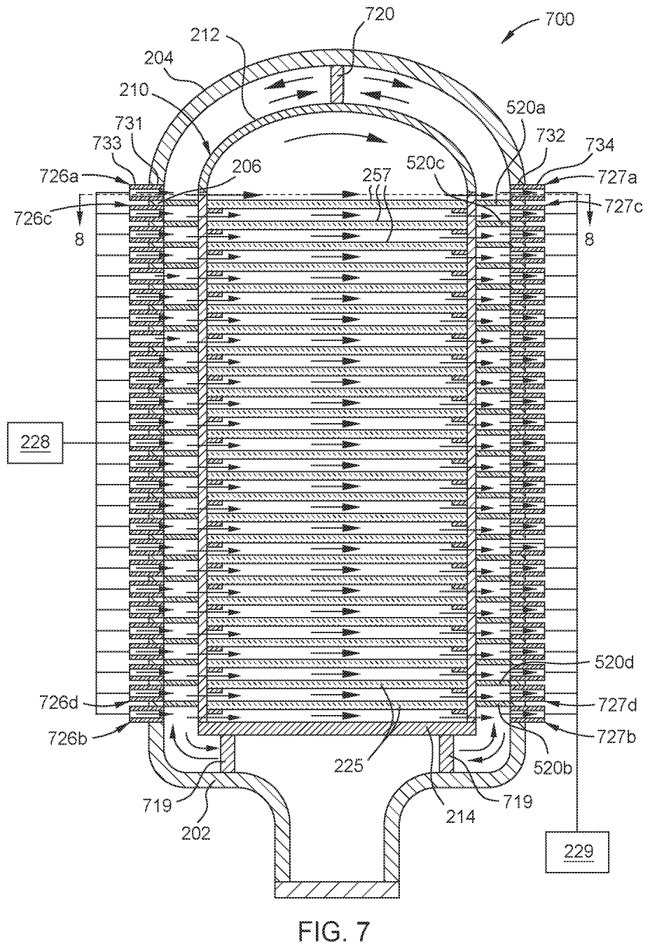

FIG. 7 is a schematic partial cross-sectional side view of a chamber 700, according to one implementation. The chamber 700 is similar to the chamber 200 shown in FIG. 2, and may include one or more features, aspects, components, operations, and/or properties thereof. The chamber 700 is similar to the chamber 500 shown in FIG. 5, and may include one or more features, aspects, components, operations, and/or properties thereof.

The chamber 700 includes a plurality of baffles 520 disposed outwardly of the cassette 210. Each of the baffles 520 has a solid ring. The plurality of baffles 520 include a first baffle 520a positioned adjacent the first outer plate 212, a second baffle 520b spaced from the first baffle 520a and positioned adjacent the second outer plate 214, and a third baffle 520c between the first baffle 520a and the second baffle 520b. In the implementation shown in FIG. 7, twenty-two baffles 520 are disposed between the first baffle 520a, and the second baffle 520b, in addition to the third baffle 520c.

The chamber 700 includes a plurality of gas inlets 726 formed in the one or more sidewalls 206. The plurality of gas inlets 726 include one or more first gas inlets 726a aligned between the first baffle 520a and the first outer plate 212, and one or more second gas inlets 726b aligned between the second baffle 520b and the second outer plate 214. The plurality of gas inlets 726 include one or more third gas inlets 726c aligned between the first baffle 520a and the third baffle 520c, and one or more fourth gas inlets 726d aligned between the second baffle 520b and the third baffle 520c.

The chamber 700 includes a plurality of gas outlets 727 formed in the one or more sidewalls 206. The plurality of gas outlets 727 include one or more first gas outlets 727a aligned between the first baffle 520a and the first outer plate 212, and one or more second gas outlets 727b aligned between the second baffle 520b and the second outer plate 214. The plurality of gas outlets 727 include one or more third gas outlets 727c aligned between the first baffle 520a and the third baffle 520c, and one or more fourth gas outlets 727d aligned between the second baffle 520b and the third baffle 520c. As described above, each of the first baffle 520a, the second baffle 520b, and the third baffle 520c has a solid ring.

Each of the plurality of gas inlets 726 includes an inlet opening 731 and each of the plurality of gas outlets 727 includes an outlet opening 732 formed in the one or more sidewalls 206. Each of the plurality of gas inlets 726 and the plurality of gas outlets 727 include a nozzle 733, 734 mounted to the one or more sidewalls 206.

In the implementation shown in FIG. 7, one or more support structures 719 are included, and the one or more support structures 719 include one or more walls. One or more walls 720 are disposed between the first outer plate 212 and the lid 204. Using the one or more walls of the one or more support structures 719 and the one or more walls 720, the gas inlets 731 are fluidly separated from (e.g., partitioned from) the gas outlets 732 in areas outwardly of the cassette 210.

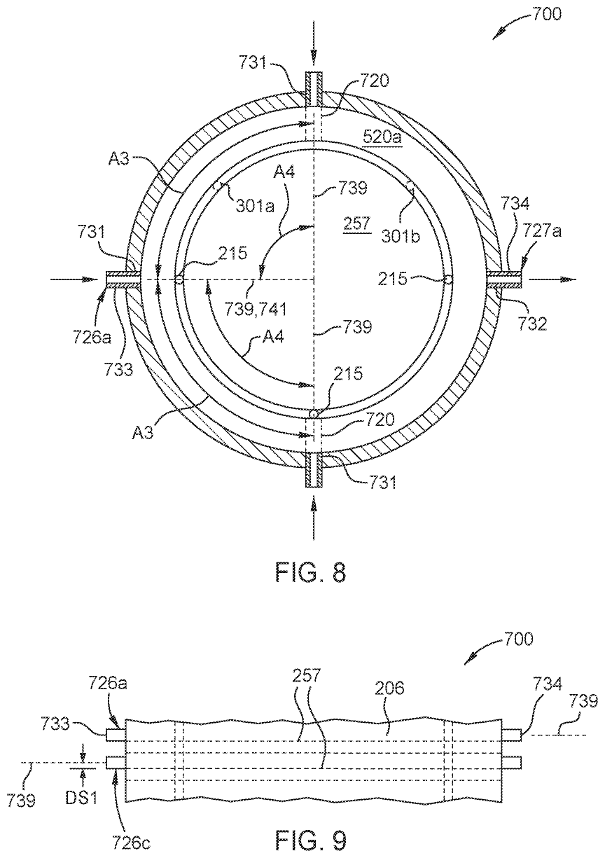

FIG. 8 is a schematic top cross-sectional view, along Section 8-8, of the chamber 700 shown in FIG. 7.

Each of the one or more first gas inlets 726a, the one or more second gas inlets 726b, the one or more third gas inlets 726c, and the one or more fourth gas inlets 726d includes a set of inlet openings 731 (three are shown in FIG. 8) spaced from each other circumferentially along the one or more sidewalls 206 by an angle A3 (as shown for the one or more first gas inlets 726a in FIG. 8). The set of inlet openings 731 can facilitate cross-flow of purge gases P1 over the substrates 225. The angle A3 is between centerline axes 739 of the inlet openings 731. In one or more embodiments, the angle A3 is within a range of 10 degrees to 90 degrees (such as 10 degrees, 20 degrees, 45 degrees, 60 degrees, or 90 degrees). In one or more embodiments, each inlet opening 731 includes a nozzle 733 in fluid communication with and/or inserted at least partially into the respective inlet opening 731. In one or more embodiments, each outlet opening 732 includes a nozzle 734 in fluid communication with and/or inserted at least partially into the respective outlet opening 732.

The present disclosure contemplates that, where each nozzle 733, 734 is shown, a series of nozzles may be used. In one or more embodiments, the inlet openings 731 and the outlet openings 732 each have a cross-sectional shape that is circular or ovular.

The present disclosure contemplates that, as is shown in FIG. 7, a single outlet opening 732 can be used for each gas outlet 727.

The one or more walls 720 are disposed at an angle A4 relative to a direction 741 extending from the gas inlets 731 and toward the gas outlets 734. The angle A4 is within a range of 20 degrees to 150 degrees, such as within a range of 20 degrees to 90 degrees or within a range of 90 degrees to 150 degrees. The angle A4 is shown as 90 degrees in FIG. 8.

FIG. 9 is a schematic partial perspective view of the chamber 700 shown in FIGS. 7 and 8, according to one implementation.

Each of the inlet openings 731 and/or the outlet opening 732 is aligned such that each centerline axis 739 is aligned at a distance DS1 from an upper surface 257 of an adjacent substrate 225 that is below the respective openings 731, 732. In one or more embodiments, the distance DS1 is 0.5 mm or higher, such as within a range of 0.5 mm to 1.5 mm. In one or more embodiments, the distance DS1 is 1.0 mm.

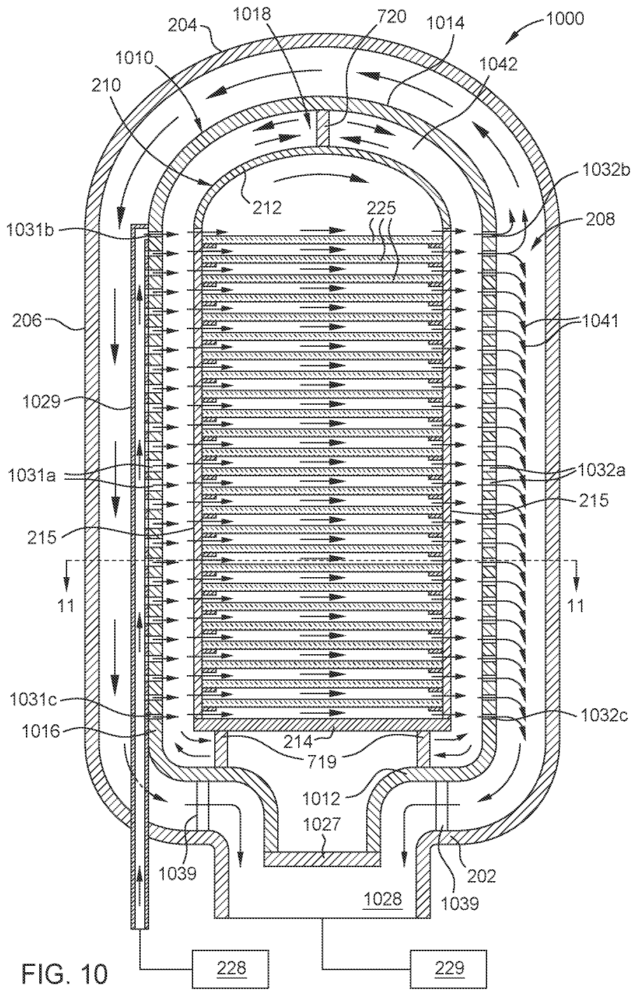

FIG. 10 is a schematic partial cross-sectional side view of a chamber 1000, according to one implementation. The chamber 1000 is similar to the chamber 200 shown in FIG. 2, and may include one or more features, aspects, components, operations, and/or properties thereof.

The chamber 1000 includes a shell 1010 disposed in the internal volume 208. The shell 1010 includes a shell base 1012, a shell lid 1014, and one or more shell walls 1016 between the shell base 1012 and the shell lid 1014. The shell base 1012, the shell lid 1014, and the one or more shell walls 1016 at least partially define a shell volume 1018. The shell 1010 includes a plurality of gas inlets 1031 formed in the one or more shell walls 1016 and spaced from each other along the one or more shell walls 1016, and a plurality of gas outlets 1032 formed in the one or more shell walls 1016 and spaced from each other along the one or more shell walls 1016. Each gas inlet 1031 and gas outlet 1032 is aligned between the first outer plate 212 and the second outer plate 214. Each gas inlet 1031 and gas outlet 1032 is aligned between the substrate supports 216 of two adjacent levels 213. The gas outlets 1032 are spaced from the gas inlets 1031 circumferentially along the one or more sidewalls 206 by about 180 degrees.

The shell 1010 can be supported in the chamber 1000, for example, using the shell base 1012 supported by the base 202 using one or more second support structures 1039. The one or more second support structures 1039 can include beams and/or can be circular, cylindrical, and/or rectangular in shape.

The cassette 210 is disposed in the shell volume 1018. The present disclosure contemplates that the baffles 220 can be omitted (as shown in FIG. 10) or included in the chamber 1000.

The chamber 1000 includes an enclosed end 1027 of the shell base 1012 and a common outlet 1028 formed in the base 202. Each of the plurality of gas inlets 1031 is in fluid communication with a common gas conduit 1029 extending through the base 202. The chamber 1000 includes an outer annular flow path 1041 about the shell 1010, and an inner annular flow path 1042 within the shell 1010. The inner annular flow path 1042 is disposed about the cassette 210, and is fluidly separated (e.g., partitioned) using the one or more walls 720 and the one or more support structures 719. The one or more purge gases P1 flow from the gas inlets 1031, over the substrates 225, through the gas outlets 1032, and out through the common outlet 1028.

In the implementation shown in FIG. 10, the one or more walls 720 are between the first outer plate 212 and the shell lid 1014.

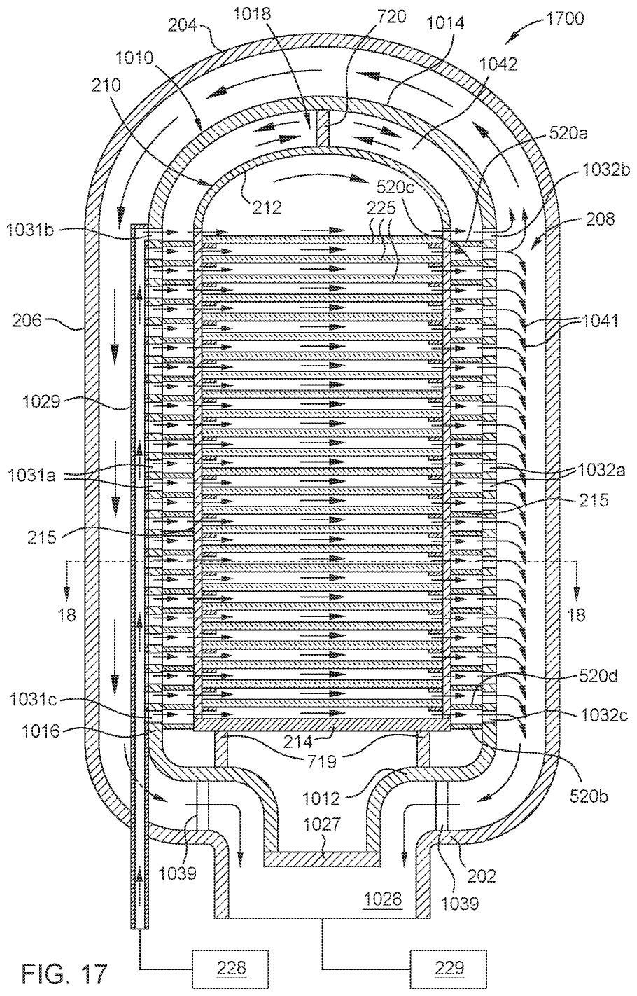

In the implementation shown in FIG. 10, the gas inlets 1031 and the gas outlets 1032 each include a size gradient that decreases from two middle inlets 1031a and two middle outlets 1032a and toward two end inlets 1031b, 1031c and two end outlets 1032b, 1032c. The present disclosure contemplates that the sizes of the gas inlets 1031 and the gas outlets 1031 can be substantially equal to each other, as shown in the implementation in FIG. 17 (see below).

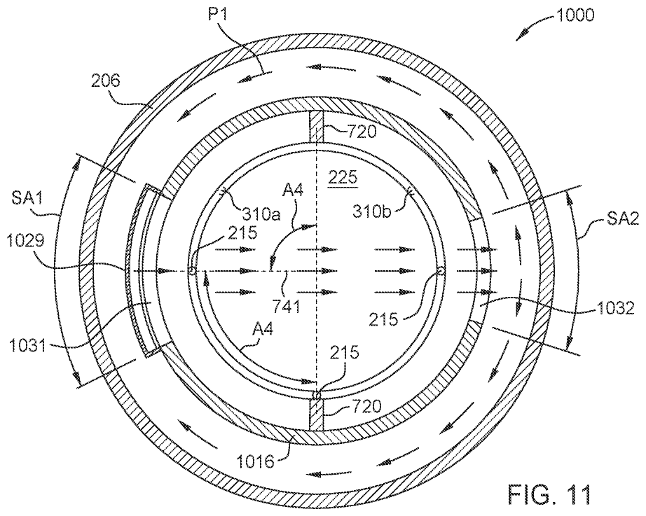

FIG. 11 is a schematic top cross-sectional view of the chamber 1000 shown in FIG. 10, along Section 11-11 shown in FIG. 10, according to one implementation. FIG. 11 shows a single level 213 of the plurality of levels 213. In the implementation shown in FIG. 11, for each level 213 one or more of the gas inlets 1031 include one or more slots that extend circumferentially along the one or more shell walls 1016 by a slot angle SA1. In one or more embodiments, the slot angle SA1 is 10 degrees or larger, such as 30 degrees or larger, for example 45 degrees, 60 degrees, 90 degrees, or 120 degrees. In one or more embodiments, for each level 213 one or more of the gas outlets 1032 include one or more slots that extend circumferentially along the one or more shell walls 1016 by a second slot angle SA2. In one or more embodiments, the second slot angle SA2 is less than the slot angle SA1. In one or more embodiments, the slot angle SA1 is within a range of 20 degrees to 40 degrees, and the slot of each gas inlet 1031 and gas outlet 1032 has a height H1 that is within a range of 0.5 mm to 1.5 mm. In one or more examples, the slot angle SA1 is 30 degrees and the height H1 is 1.0 mm.

The slot angle SA1 can facilitate, for example, a larger coverage of substrates 225 with the purge gas(es) P1 to facilitate larger forced convective effects. The chamber 1000 facilitates a heat transfer rate across a batch plurality of substrates 225 (such as 25 substrates) that is 0.35 degrees Celsius per second or higher (such as 0.375 degrees Celsius per second or higher).

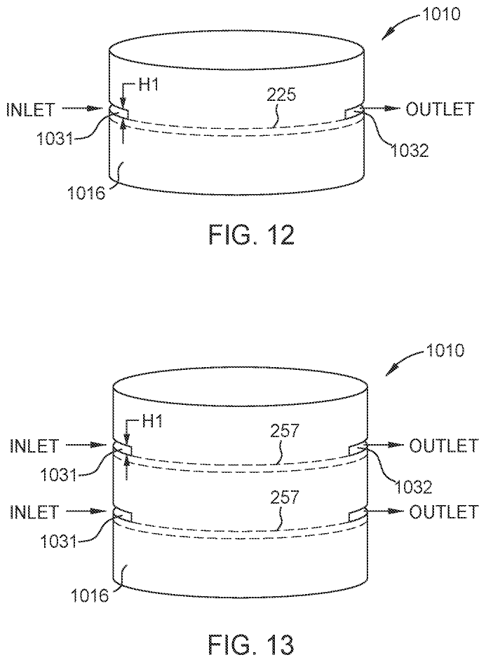

FIG. 12 is a schematic partial perspective view of the shell 1010 shown in FIG. 11, according to one implementation.

FIG. 13 is a schematic partial perspective view of the shell 1010 shown in FIG. 10, according to one implementation.

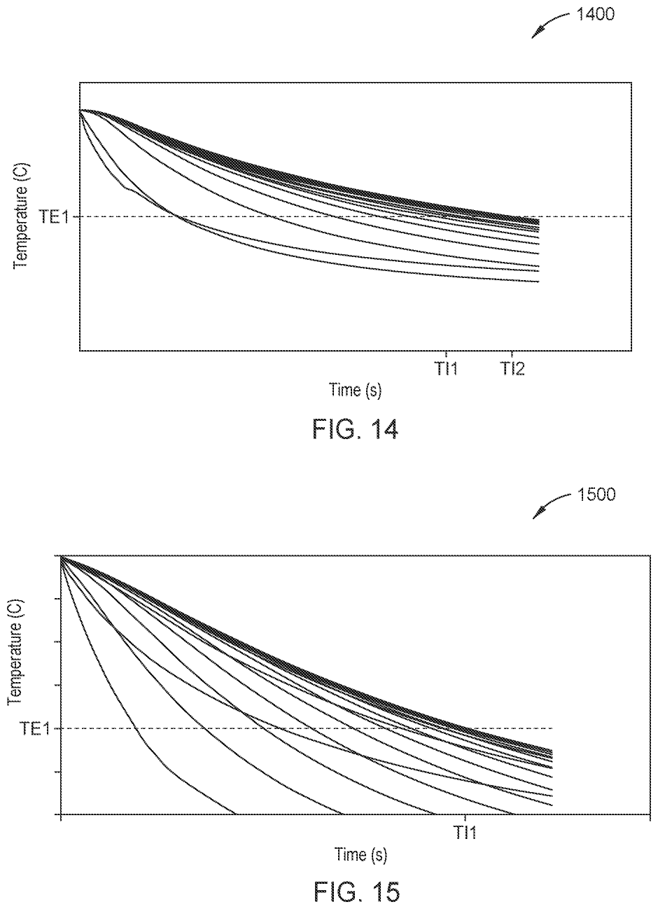

FIGS. 14 and 15 are schematic graphical views of graphs 1400, 1500 showing temperature (in degrees Celsius) versus time (in seconds), according to one or more implementations. Each profile corresponds to the temperature of a respective substrate in each graph 1400, 1500.

In the graph 1500 of FIG. 15, a chamber including subject matter described herein is used to cool a plurality of substrates to a target temperature TE1. In the graph 1400 of FIG. 14, a chamber of another configuration is used to cool a plurality of substrates to the same target temperature TE1 using the same parameters (e.g., purge gas composition, purge gas temperature, and purge gas flow rate).

As shown in FIG. 15, using subject matter described herein, all of the substrates are cooled to the target temperature TE1 at a time TI1 that is quicker than the time TI2 shown in FIG. 14. A faster heat transfer time facilitates, for example, increased throughput and reduced costs.

The time TI1 can be about 80% of the time TI2, exhibiting a cycle time reduction that is 20% or higher. Using adjustability (such as by increasing a gas flow rate of purge gas(es)), the time TI1 can be 50%-60% of the time TI2, which can exhibit a cycle time reduction that is 40%-50% or higher.

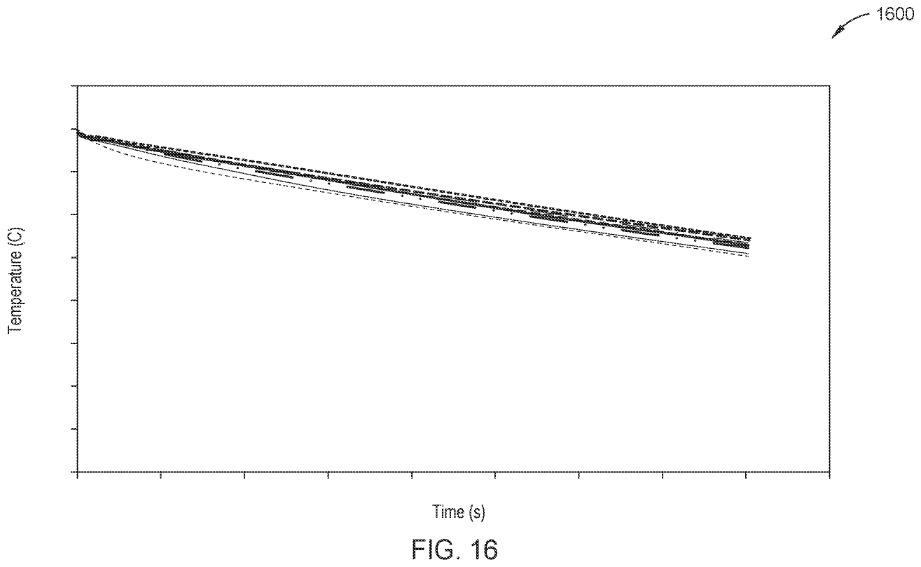

FIG. 16 is a schematic graphical view of a graph 1600 showing temperature (in degrees Celsius) versus time (in seconds), according to one implementation.

As shown in FIG. 16, using subject matter described herein, a plurality of substrates are cooled at more uniform cooling rates than the profiles shown in FIG. 14, for example.

FIG. 17 is a schematic partial cross-sectional side view of a chamber 1700, according to one implementation. The chamber 1700 is similar to the chamber 1000 shown in FIG. 10, and may include one or more features, aspects, components, operations, and/or properties thereof.

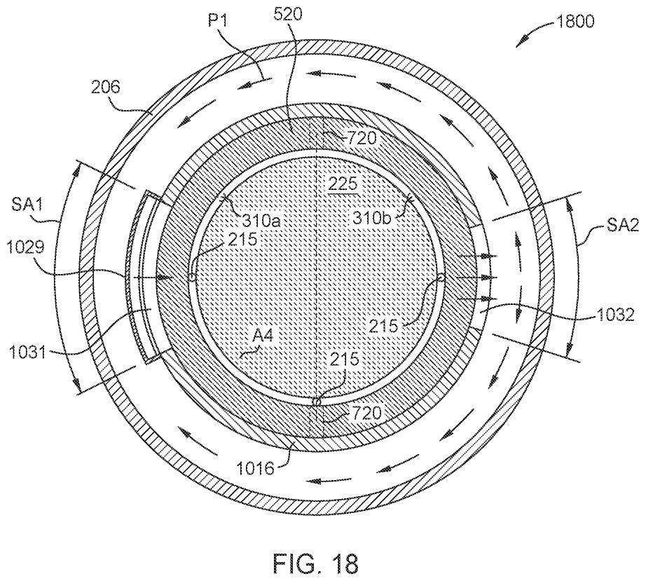

FIG. 18 is a schematic top cross-sectional view of the chamber 1700 shown in FIG. 17, along Section 18-18 shown in FIG. 17, according to one implementation. FIG. 18 shows a single level 213 of the plurality of levels 213.

Benefits of the present disclosure include batch heating and/or cooling of substrates at more uniform heating rates and/or cooling rates; increased batch capacity (e.g., 25 or more substrates); reduced cycle times and processing times; increased throughout; increased cooling and/or heating rates; adjustability of gas flow rates and heat transfer rates; modularity in application; reduced or eliminated bottleneck effects; and increased heat transfer coefficients (such as convective heat transfer coefficients). Such benefits are facilitated in a manner that is simple, cost-effective, and easy to use. Such benefits of the present application are facilitated by implementations of the present disclosure. As an example, one or more implementations (such as the chamber 700) facilitate the ability and flexibility of individually adjusting the flow rate of purge gas(es) at each level using each individual gas inlet 731 and gas outlet 732 such that all of the substrates 225 are cooled or heated to the target temperature at substantially the same time. Reaching the target temperature at substantially the same time facilitates time savings (including reduced delays for subsequent processing) and increased throughput.

It is contemplated that aspects described herein can be combined. For example, one or more features, aspects, components, operations, and/or properties of the system 100, the chamber 200, the chamber 500, the chamber 700, the chamber 1000, and/or the chamber 1700 can be combined. It is further contemplated that any combination(s) can achieve the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A chamber for use in semiconductor manufacturing, comprising:
a base;
a lid;
one or more sidewalls between the base and the lid, the base, the lid, and the one or more sidewalls at least partially defining an internal volume;
a cassette disposed in the internal volume, the cassette comprising:
a first outer plate,
a second outer plate spaced from the first outer plate, and
a plurality of levels between the first outer plate and the second outer plate, the plurality of levels comprising a plurality of substrate supports spaced from each other; and
one or more baffles disposed outwardly of the cassette.

2. The chamber of claim 1, wherein the one or more baffles are mounted to the one or more sidewalls, and the cassette further comprises:
a plurality of support rods extending between the first outer plate and the second outer plate, wherein the plurality of support rods are positioned between the one or more baffles and the plurality of substrate supports.

3. The chamber of claim 2, wherein for each level of the plurality of levels a set of substrate supports are coupled to the plurality of support rods and extending inwardly relative to the plurality of support rods.

4. The chamber of claim 1, wherein the one or more baffles each comprise an arcuate ring having a flow opening to define an arcuate ring segment.

5. The chamber of claim 4, wherein the flow opening is defined by an angle that is 10 degrees or larger.

6. The chamber of claim 4, wherein the one or more baffles comprise:
a first baffle having a first flow opening; and
a second baffle spaced from the first baffle, the second baffle having a second flow opening, wherein the second flow opening is offset from the first flow opening in a direction from the second outer plate and toward the first outer plate.

7. The chamber of claim 6, further comprising:
one or more gas inlets formed in the lid and outwardly of the first outer plate; and
one or more gas outlets formed in the base and outwardly of the second outer plate.

8. The chamber of claim 1, wherein the one or more baffles comprise:
a first baffle having a first flow opening;
a second baffle spaced from the first baffle, the second baffle having a second flow opening; and
a third baffle between the first baffle and the second baffle, the third baffle having a solid ring.

9. The chamber of claim 8, further comprising:
a first gas inlet formed in the one or more sidewalls on a first side of the third baffle;
a second gas inlet formed in the one or more sidewalls on a second side of the third baffle;
a first gas outlet formed in the lid and outwardly of the first outer plate; and
a second gas outlet formed in the base and outwardly of the second outer plate.

10. The chamber of claim 1, wherein each of the first outer plate, the second outer plate, and the one or more baffles is formed of aluminum.

11. A chamber applicable for use in semiconductor manufacturing, comprising:
a base;
a lid;
one or more sidewalls between the base and the lid, the base, the lid, and the one or more sidewalls at least partially defining an internal volume;
a cassette disposed in the internal volume, the cassette comprising:
a first outer plate,
a second outer plate spaced from the first outer plate, and
a plurality of levels between the first outer plate and the second outer plate, the plurality of levels comprising a plurality of substrate supports spaced from each other; and
a plurality of baffles disposed outwardly of the cassette, the plurality of baffles comprising:
a first baffle positioned adjacent the first outer plate,
a second baffle spaced from the first baffle and positioned adjacent the second outer plate, and
a third baffle between the first baffle and the second baffle; and
a plurality of gas inlets formed in the one or more sidewalls, the plurality of gas inlets comprising:
one or more first gas inlets aligned between the first baffle and the first outer plate,
one or more second gas inlets aligned between the second baffle and the second outer plate,
one or more third gas inlets aligned between the first baffle and the third baffle, and
one or more fourth gas inlets aligned between the second baffle and the third baffle.

12. The chamber of claim 11, further comprising a plurality of gas outlets formed in the one or more sidewalls, the plurality of gas outlets comprising:
one or more first gas outlets aligned between the first baffle and the first outer plate,
one or more second gas outlets aligned between the second baffle and the second outer plate,
one or more third gas outlets aligned between the first baffle and the third baffle, and
one or more fourth gas outlets aligned between the second baffle and the third baffle.

13. The chamber of claim 12, wherein each of the first baffle, the second baffle, and the third baffle has a solid ring.

14. The chamber of claim 11, wherein each of the plurality of gas inlets includes an inlet opening formed in the one or more sidewalls, and a nozzle mounted to the one or more sidewalls.

15. The chamber of claim 11, wherein each of the one or more first gas inlets, the one or more second gas inlets, the one or more third gas inlets, and the one or more fourth gas inlets includes a set of inlet openings spaced from each other circumferentially along the one or more sidewalls by an angle, and the angle is within a range of 10 degrees to 90 degrees.

16. A chamber applicable for use in semiconductor manufacturing, comprising:
a base;
a lid;
one or more sidewalls between the base and the lid, the base, the lid, and the one or more sidewalls at least partially defining an internal volume;
a shell disposed in the internal volume, the shell comprising:
a shell base,
a shell lid, and
one or more shell walls between the shell base and the shell lid, the shell base, the shell lid, and the one or more shell walls at least partially defining a shell volume,
a plurality of gas inlets formed in the one or more shell walls and spaced from each other along the one or more shell walls, and
a plurality of gas outlets formed in the one or more shell walls and spaced from each other along the one or more shell walls; and
a cassette disposed in the shell volume, the cassette comprising:
a first outer plate,
a second outer plate spaced from the first outer plate, and
a plurality of levels between the first outer plate and the second outer plate, the plurality of levels comprising a plurality of substrate supports spaced from each other.

17. The chamber of claim 16, further comprising a common outlet formed in the base, wherein each of the plurality of gas inlets is in fluid communication with a common gas conduit extending through the base.

18. The chamber of claim 16, further comprising an outer annular flow path about the shell.

19. The chamber of claim 16, wherein each of the plurality of gas inlets and each of the plurality of gas outlets comprises a slot that extends circumferentially along the one or more shell walls by a slot angle.

20. The chamber of claim 19, wherein the slot angle is within a range of 10 degrees to 120 degrees, and the slot has a height that is within a range of 0.5 mm to 1.5 mm.
